(19) United States
(12) Patent Application Publication
(10) Pub. No.: US 2026/0074151 A1
(43) Pub. Date: Mar. 12, 2026

(54) UNIFORM PIXELATED MICROWAVE PLASMA SOURCE WITH SUBSTRATE ROTATION

(71) Applicant: Applied Materials, Inc., Santa Clara, CA (US)

(72) Inventors: JOSEPH AUBUCHON, San Jose, CA (US); TZA-JING GUNG, San Jose, CA (US)

(21) Appl. No.: 18/829,095

(22) Filed: Sep. 9, 2024

(51) Int. Cl. H01J 37/32

(52) U.S. Cl. CPC H01J 37/32247; H01J 37/32201; H01J 37/32715; H01J 2237/20214

(57) ABSTRACT

Embodiments described herein relate to an apparatus that includes a dielectric plate, and a plurality of dielectric resonators coupled to the dielectric plate. In an embodiment, the plurality of dielectric resonators are distributed across the dielectric plate in a pattern that is asymmetric in order to provide a plasma uniform flux density to an underlying substrate as the substrate is rotated.

### BACKGROUND

### 1) Field

Embodiments relate to the field of semiconductor manufacturing and, in particular, microwave plasma sources with a plurality of dielectric resonators that are distributed in a pattern to provide a uniform plasma flux to the substrate.

### 2) Description of Related Art

Microwave plasma sources provide different distributions of species than lower frequency plasma sources (e.g., RF plasma sources) that are typically used in semiconductor processing operations, such as deposition processes, etching process, plasma treatment processes, or the like. For example, microwave plasma sources typically provide higher density plasmas with lower energy distribution functions. However, existing microwave plasma source designs are limited in their ability to provide good plasma uniformity. One proposed solution to improve plasma uniformity is to provide a pixelated plasma source. In a pixelated plasma source, a plurality of microwave dielectric resonators are used to provide multiple microwave injection points to the chamber.

However, the size of the dielectric resonators is constrained by the resonance characteristics dictated by the dielectric constant of the material used for the dielectric resonator. The limited size options for the dielectric resonators may result in the need for many dielectric resonators in order to provide a uniform plasma. Since each of the dielectric resonators have their own microwave amplifier and corresponding cabling, the cost of such systems can grow rapidly. Additionally, even though the dielectric resonators are independently controllable, the plasma uniformity may still be difficult to optimize due to the overlap of microwave power emitted from neighboring dielectric resonators.

### SUMMARY

Embodiments described herein relate to an apparatus that includes a dielectric plate, and a plurality of dielectric resonators coupled to the dielectric plate. In an embodiment, the plurality of dielectric resonators are distributed across the dielectric plate in a pattern that is asymmetric.

Embodiments described herein relate to an apparatus that includes a chamber, and a microwave plasma source coupled to the chamber. In an embodiment, the microwave plasma source includes a plurality of dielectric resonators that are distributed over a dielectric plate in a pattern that does not include an axis of symmetry. In an embodiment, a pedestal is provided within the chamber, and the pedestal is configured to be rotated.

Embodiments described herein relate to a method that includes rotating a substrate on a pedestal within a chamber that includes a microwave plasma source. In an embodiment, a plurality of dielectric resonators are distributed across the chamber in a pattern that does not have an axis of symmetry. In an embodiment, the method further includes processing the substrate with a plasma induced by the plurality of dielectric resonators while the substrate is rotated.

### BRIEF DESCRIPTION OF THE DRAWINGS

FIG. 1A is a cross-sectional illustration of a portion of a microwave plasma source that illustrates a single dielectric resonator coupled to a microwave power amplifier, in accordance with an embodiment.

FIG. 1B is a plan view illustration of a microwave plasma source that comprises a plurality of dielectric resonators distributed across a dielectric plate with a symmetric pattern that has at least one axis of symmetry, in accordance with an embodiment.

FIG. 1C is a cross-sectional illustration of the microwave plasma source in FIG. 1B that illustrates a relatively high degree of plasma flux non-uniformity, in accordance with an embodiment.

FIG. 2A is a plan view illustration of an array of dielectric resonators that is provided over a rotating substrate, in accordance with an embodiment.

FIG. 2B is a plan view illustration of an array of dielectric resonators in a pattern without an axis of symmetry that is provided over a rotating substrate, in accordance with an embodiment.

FIG. 3A is a plan view illustration of an array of dielectric resonators in a pattern without an axis of symmetry that is provided over a rotating substrate, in accordance with an embodiment.

FIG. 3B is a graph depicting a total flux of a plasma and the flux of each dielectric resonator in FIG. 3A, in accordance with an embodiment.

FIG. 4A is a plan view illustration of an array of dielectric resonators in a pattern without an axis of symmetry that is provided over a rotating substrate, in accordance with an embodiment.

FIG. 4B is a graph depicting a total flux of a plasma and the flux of each dielectric resonator in FIG. 4A, in accordance with an embodiment.

FIG. 5 is a cross-sectional illustration of a processing tool that comprises a microwave plasma source with a plurality of dielectric resonators arranged over a dielectric plate in an asymmetric pattern, in accordance with an embodiment.

FIG. 6 is a flow diagram depicting a process for processing a substrate in a chamber that comprises a microwave plasma source with a plurality of dielectric resonators arranged over a dielectric plate in an asymmetric pattern, in accordance with an embodiment.

FIG. 7 illustrates a block diagram of an exemplary computer system that may be used in conjunction with a processing tool, in accordance with an embodiment.

### DETAILED DESCRIPTION

Embodiments described herein include microwave plasma sources with a plurality of dielectric resonators that are distributed in a pattern to provide a uniform plasma flux to the substrate. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, microwave plasma sources may suffer from poor plasma uniformity. That is, the flux of species from plasma that are delivered to an underlying substrate may not be consistent across a surface of the substrate. Such non-uniformity is detrimental to processing operations (e.g., etching, deposition, treatment, etc.) since the processed substrate will not have a uniform surface (e.g., with respect to film thickness, feature profile, chemical composition, etc.). This can lead to defective devices on the substrate and reduce product yield. Accordingly, the benefits of microwave plasmas, such as high plasma densities and low energy distribution functions cannot be fully utilized.

One solution for improving microwave plasma uniformity is to use a pixelated (or modular) microwave plasma approach. In such an embodiment, a plurality of dielectric resonators (which may also be referred to as microwave antennas or applicators) are distributed across a surface of a dielectric plate. The plurality of dielectric resonators are each coupled to their own microwave power amplifier and can be independently controlled. The layout pattern of the dielectric resonators may also be a symmetric pattern in order to improve plasma uniformity. For example, the pattern may sometimes be radially symmetric. In order to provide a desired plasma uniformity, a large number of dielectric resonators may be used. For example ten or more dielectric resonators or fifteen or more dielectric resonators may be used in high volume manufacturing (HVM) semiconductor processing tools. This increases the overall cost and complexity of such tools.

Additionally, the use of a modular microwave plasma source still does not provide the desired plasma uniformity in some applications. This is because each dielectric resonator provides a flux distribution that spreads wider than the diameter of the dielectric resonator. As such, the flux from neighboring dielectric resonators will add to each other, and it is difficult to provide a net plasma flux uniformity across the entire width of the plasma. In order to reach acceptable plasma flux uniformities, precise control of processing conditions and/or hardware configurations are needed. This may reduce flexibility of the processing tool to operate over large process windows, and the capabilities of the processing tool may be limited.

Accordingly, embodiments disclosed herein may include a microwave plasma source that comprises a plurality of microwave dielectric resonators that are arranged in an asymmetric pattern. That is, the pattern may not have any axis of symmetry. The asymmetric pattern may still provide dielectric resonators that supply microwave power to substantially the entire radius of the underlying substrate. In order to provide a uniform plasma flux without a symmetric pattern of the dielectric resonators, the underlying substrate may be rotated. The rotation allows for a reduction in the number of dielectric resonators (which can reduce the cost and complexity of the microwave plasma source).

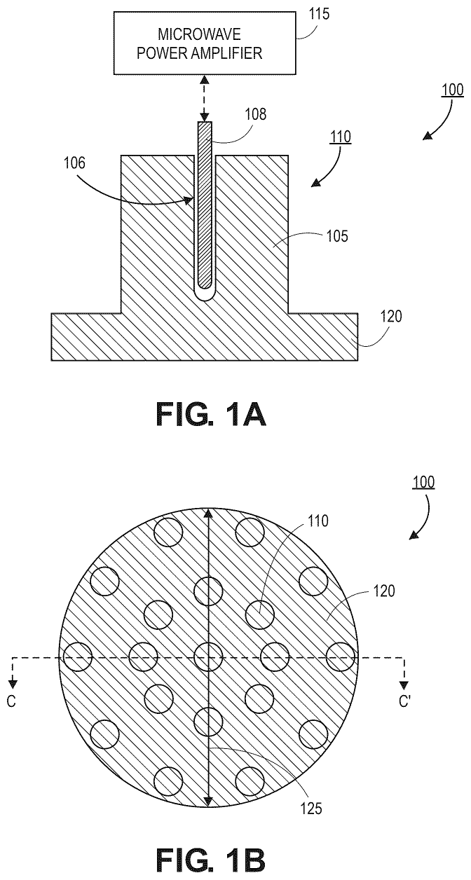

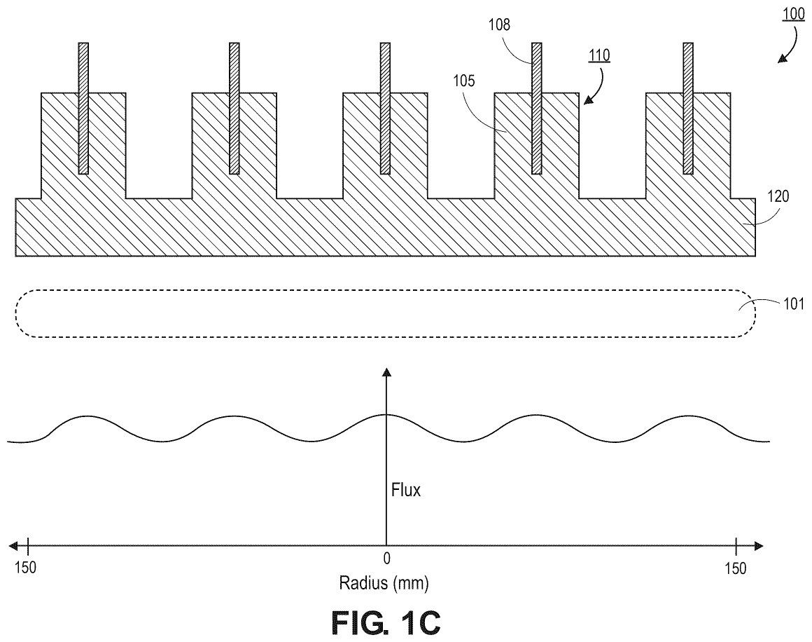

Referring now to FIG. 1A, a cross-sectional illustration of a portion of a microwave plasma source 100 is shown, in accordance with an embodiment. In an embodiment, the microwave plasma source 100 may comprise a dielectric plate 120 and a dielectric resonator 110 coupled to the dielectric plate 120. In the illustrated embodiment, the dielectric resonator 110 and the dielectric plate 120 are a monolithic structure. Though, in other embodiments, the dielectric plate 120 and the dielectric resonator 110 may comprise discrete components. In an embodiment, the dielectric resonator 110 and the dielectric plate 120 may comprise any suitable dielectric material. For example, the dielectric resonator 110 and the dielectric plate 120 may comprise alumina or the like.

In an embodiment, the dielectric resonator 110 may comprise a dielectric puck 105. The dielectric puck 105 may be sized in order to provide a resonant cavity based on the frequency of the microwave power and the dielectric constant of the dielectric puck 105. In some embodiments, the dielectric puck 105 is cylindrical. Though, other three dimensional shapes may also be used for the dielectric puck 105 in other embodiments. While not shown, an electrically conductive housing or shielding may be provided along sidewalls of the dielectric puck 105.

In an embodiment, the dielectric resonator 110 may also comprise a hole 106 that passes into the dielectric puck 105. An electrically conductive pin 108 may be inserted into the hole 106. While the hole 106 and pin 108 are shown as being at an axial center of the dielectric puck 105, it is to be appreciated that the hole 106 and the pin 108 may be located at any location within the dielectric puck 105 and/or oriented at any angle relative to the dielectric plate. Further, any suitable hole 106 depth, hole 106 shape, pin 108 shape, and/or the like may be used for the dielectric resonator 110.

In an embodiment, the pin 108 may be electrically coupled to a microwave power amplifier 115. The electrical coupling between the pin 108 and the microwave power amplifier 115 may include any number of components, cables, and/or the like. For example, an impedance match, a coaxial cable, circuitry, and/or the like may be provided along an electrical path between the pin 108 and the microwave power amplifier 115.

In an embodiment, microwave power from the microwave power amplifier is propagated to the pin 108. The resonant cavity of the dielectric puck 105 allows for the microwave power to be coupled into the dielectric material and propagate into the dielectric plate 120. The bottom surface of the dielectric plate 120 may be within a vacuum chamber that can support a plasma that is ignited and sustained by the microwave power.

Referring now to FIG. 1B, a plan view illustration of a microwave plasma source 100 is shown, in accordance with an embodiment. The microwave plasma source 100 may comprise a dielectric plate 120 with a plurality of dielectric resonators 110 distributed across the dielectric plate 120. The dielectric resonators 110 in FIG. 1B may each be similar to the dielectric resonator 110 in FIG. 1A. For example, the dielectric resonators 110 may each comprise a conductive pin that is inserted into a hole of the dielectric resonator 110. In an embodiment, each of the dielectric resonators 110 may be electrically coupled to different microwave power amplifiers (not shown). As such, the dielectric resonators 110 may be independently controlled.

In an embodiment, the dielectric resonators 110 may be arranged across the dielectric plate 120 in a pattern that is symmetric. For example, the pattern may have an axis of symmetry 125 that passes through a center-point (or origin) of the dielectric plate 120. In the embodiment shown in FIG. 1B, the pattern may be radially symmetric such that there are a plurality of axes of symmetry 125 that pass through the center-point of the dielectric plate 120. In FIG. 1B, there are nineteen dielectric resonators 110. Though, embodiments may include any number of dielectric resonators 110 in the microwave plasma source 100.

As noted above, such a construction for the microwave plasma source 100 may still suffer from plasma non-uniformities even though a radially symmetric pattern is used for the layout of the dielectric resonators 110. This may be due in part to the distribution of microwave power that is emitted from each of the dielectric resonators 110. For example, the distribution for each dielectric resonator 110 may have a peak at an axial center of the dielectric resonator 110, with tail ends that extend out past a width of the dielectric resonator 110. The tail ends of the distribution may overlap the microwave power of one or more of the other dielectric resonators 110. As such, it may be difficult to provide a uniform level of microwave power across the dielectric plate 120 due to the microwave power added by each dielectric resonator 110. Even with individual control of the dielectric resonators 110, a desired level of uniformity may not be obtainable. Even when acceptable uniformity is provided, the process window may be small. As such, the capability of the processing tool coupled to the microwave plasma source 100 is not fully realized.

Referring now to FIG. 1C, a cross-sectional illustration of the microwave plasma source 100 in FIG. 1B along line C-C′ is shown, in accordance with an embodiment. As shown, the microwave power emitted by the dielectric resonators 110 and spread through the dielectric plate 120 can be used to ignite and/or sustain a plasma 101. The microwave plasma source 100 may be coupled to a chamber (not shown) and the plasma 101 may be formed within the chamber. As described above, the microwave power distribution emitted by the microwave plasma source 100 may be non-uniform. This can lead to a plasma 101 that has a non-uniform plasma flux towards a substrate (not shown) that is provided below the dielectric plate 120.

In FIG. 1C, the graph below the plasma 101 illustrates the non-uniform plasma flux over a width of a substrate (not shown). As shown, the plasma flux may peak below center-points of the dielectric resonators 110 and have valleys between the dielectric resonators 110. This wave-like pattern can lead to unacceptable process non-uniformities on the substrate. For example, a degree of uniformity of the plasma 101 may be approximately 90% or less, approximately 80% or less, or approximately 75% or less. As used herein, the degree of uniformity a may be described by Equation 1, where nmax is the peak of the flux distribution across the substrate, nmin is the minimum of the flux distribution across the substrate, and nave is the average of the flux distribution across the substrate.

$$α = ( 1 - \frac{{n}_{max} - {n}_{min}}{2 {n}_{ave}} ) \times 100 \% \qquad Equation 1$$

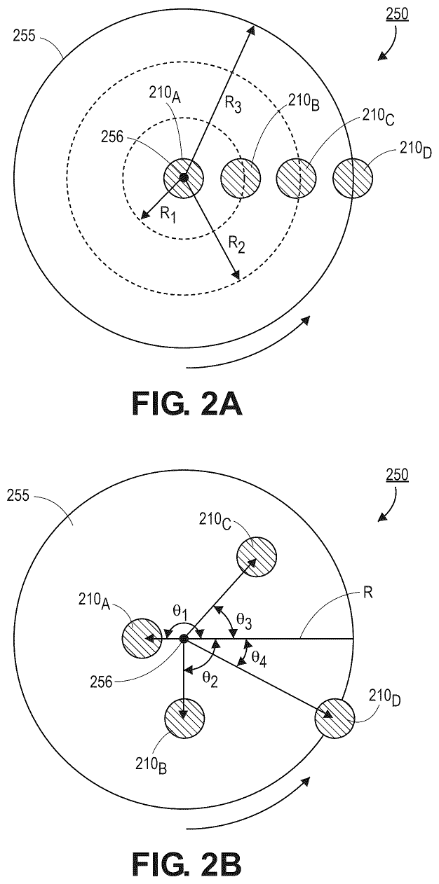

Accordingly, embodiments disclosed herein aim to improve the degree of uniformity of the plasma flux across the underlying substrate. One approach to improve the degree of uniformity is to provide dielectric resonators across a diameter at multiple distances from the origin of the substrate. Instead of a radially symmetric pattern, the substrate may be rotated. In order to provide even greater flexibility in tuning the degree of plasma uniformity, the dielectric resonators may be provided at different distances from the origin of the substrate and at different angles relative to a radius of the substrate while rotating the substrate. This provides the ability to put more dielectric resonators proximate to an outer edge of substrate in order to increase the microwave power delivered to the edges of the substrate. In addition to allowing for improved degrees of plasma flux uniformity, such embodiments also allow for a reduction in the number of dielectric resonators. This reduces cost and complexity of the microwave plasma source as well. Examples of such embodiments are shown in FIGS. 2A and 2B.

Referring now to FIG. 2A, a plan view illustration of a portion of a processing tool 250 is shown, in accordance with an embodiment. In an embodiment, the processing tool may comprise a plurality of dielectric resonators 210. For example, four dielectric resonators 210A-210D are shown in FIG. 2A. The dielectric resonators 210 may be provided over a dielectric plate (not shown) similar to embodiments described above. As shown, a substrate 255 may be provided below the dielectric resonators 210. The substrate 255 may be rotated (as indicated by the curved arrow) in order to repeatedly pass below the array of dielectric resonators 210.

In an embodiment, the plurality of dielectric resonators 210 may be spaced apart from the origin 256 by different radii R₁-R₃. The first dielectric resonator 210 may be provided with a center-point over the origin 256. As such, the microwave power is distributed across an entire radius of the substrate 255. Rotation of the substrate 255 allows for all portions of the substrate 255 to be exposed to the plasma generated below the dielectric resonators 210.

In order to improve the degree of plasma flux uniformity, the dielectric resonators 210 may also be arranged in an asymmetric pattern, as shown in FIG. 2B. As used herein, an asymmetric pattern may be a pattern of the plurality of resonators 210 that does not have an axis of symmetry. An axis of symmetry may refer to a line that passes through the pattern that divides the pattern into two mirror images of each other on either side of the line. In FIG. 2B, the plurality of resonators 210 may each have a center-point that is provided at a different radius from the origin 256. Additionally, each of the plurality of resonators 210 may be oriented at a different angle θ from a radius R of the substrate 255. For example, the plurality of dielectric resonators 210A-210D are each oriented at different angles θ₁-θ₄ with respect to the radius R, respectively. In some embodiments both the distance from the origin 256 and the angle θ with respect to the radius R of the substrate 255 are different for each of the plurality of resonators 210. Though, in other embodiments, two or more dielectric resonators 210 may have either the same distance from the origin 256 or the same angle θ relative to the radius R of the substrate 255.

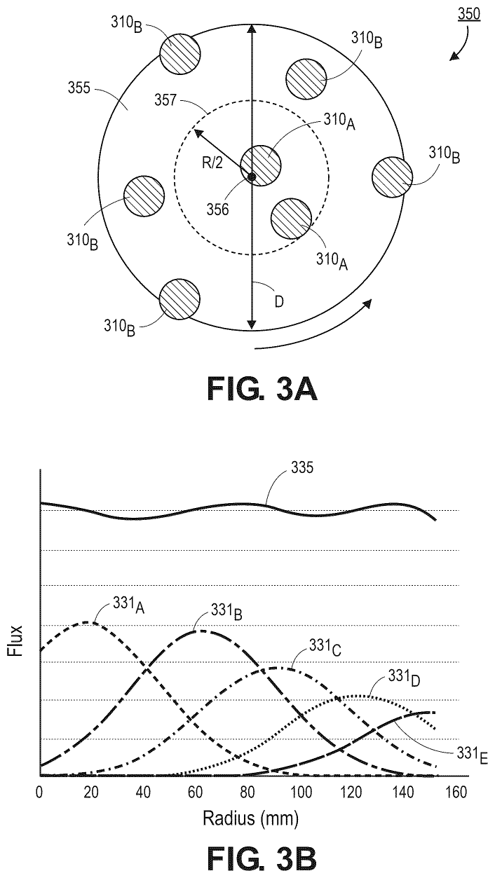

Referring now to FIG. 3A, a plan view illustration of a portion of a processing tool 350 is shown, in accordance with an embodiment. In an embodiment, the processing tool 350 may comprise a plurality of dielectric resonators 310. The dielectric resonators 310 may be similar to any of the dielectric resonators described in greater detail herein. Additionally, the dielectric resonators 310 may be provided over a dielectric plate (not shown) similar to other embodiments described herein. The dielectric resonators 310 may be arranged over a substrate 355. The substrate 355 may be rotated, as indicated by the curved arrow.

In an embodiment, the plurality of dielectric resonators 310 may be arranged in a pattern over the substrate 355. The pattern may be an asymmetric pattern that does not include an axis of symmetry. For example, any diameter D formed through the origin 356 of the substrate 355 at any angle may not be an axis of symmetry for the pattern of dielectric resonators 310. In some embodiments both the distance from the origin 356 of the substrate 355 to a center-point of each dielectric resonator 310 and an angle θ with respect to a radius R of the substrate 355 are different for each of the plurality of resonators 310. Though, in other embodiments, two or more dielectric resonators 310 may have either the same distance from the origin 356 to a center-point of the dielectric resonator 310 or the same angle θ relative to a radius R of the substrate 355. In the illustrated embodiment, the plurality of dielectric resonators 310 comprise a set of seven dielectric resonators 310. Though, embodiments may include any number of dielectric resonators 310.

As can be appreciated, rotating the substrate 355 may result in uneven exposure along the radius of the substrate 355. That is, a point on a surface of the substrate 355 proximate to the origin 356 will be exposed to more plasma flux generated by a single overlying dielectric resonator 310 positioned near the origin compared to the exposure to plasma flux for a point on the surface of the substrate 355 proximate to an edge of the substrate 355 provided by a single dielectric resonator 310 near an edge of the substrate 355. This is due to points near the origin 356 moving slower than points near the edge of the substrate 355 during rotation.

Accordingly, embodiments may account for the lower effective plasma flux towards the edge of the substrate 355 by providing more dielectric resonators 310 proximate to the edge of the substrate 355. For example, in FIG. 3A, a first set of dielectric resonators 310A may be proximate to the origin 356, and a second set of dielectric resonators 310B may be proximate to the edge of the substrate 355. More specifically, the first set of dielectric resonators 310A may be distinguished from the second set of dielectric resonators 310B by a position of a center point of each dielectric resonator relative to a boundary 357. For example, the boundary 357 may be one-half of the radius of the substrate 355 (e.g., R/2). As shown in FIG. 3A, the first set of dielectric resonators 310A comprises two dielectric resonators 310A, and the second set of dielectric resonators 310B comprises five dielectric resonators 310B. Though, any suitable distribution of dielectric resonators between the two sets may be used in some embodiments.

While positioning of the dielectric resonators 310 may be used to balance the effective plasma flux along each radial position of the substrate 355, other embodiments may also include controlling power settings for the dielectric resonators 310. For example, the dielectric resonators 310 closer to an edge of the substrate 355 may be held at a higher power level than the dielectric resonators 310 closer to the origin 356.

Referring now to FIG. 3B, a graph of the plasma flux relative to a radial position from the origin (i.e., 0 mm) to an edge of the substrate (i.e., 150 mm) is shown, in accordance with an embodiment. The graph shows the relative contribution 331_{A}-331_{E} to the plasma flux from each of the individual dielectric resonators 310. When those contributions 331 are summed together, a total plasma flux 335 is provided. Compared to the total plasma flux shown in FIG. 1C, the degree of uniformity is significantly improved. For example, the degree of uniformity may be approximately 90% or higher, or approximately 95% or higher.

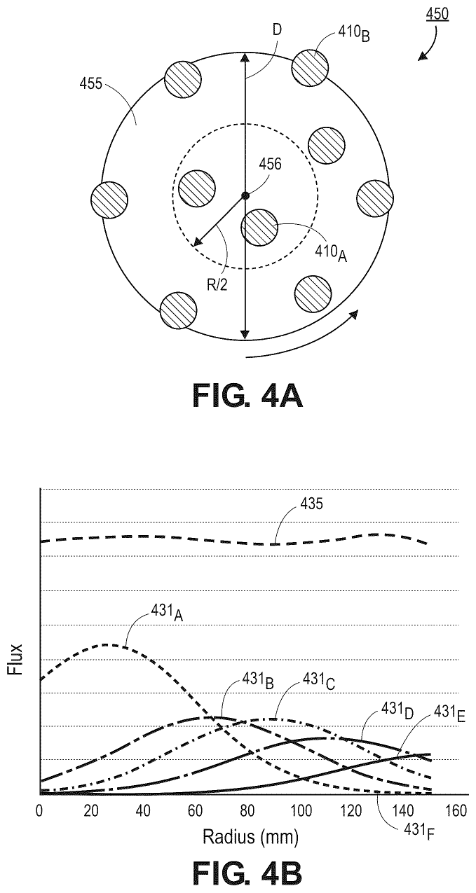

Referring now to FIG. 4A, a cross-sectional illustration of a portion of a processing tool 450 is shown, in accordance with an additional embodiment. In an embodiment, the processing tool 450 may comprise a plurality of dielectric resonators 410. The dielectric resonators 410 may be similar to any of the dielectric resonators described in greater detail herein. Additionally, the dielectric resonators 410 may be provided over a dielectric plate (not shown) similar to other embodiments described herein. The dielectric resonators 410 may be arranged over a substrate 455. The substrate 455 may be rotated, as indicated by the curved arrow.

In an embodiment, the plurality of dielectric resonators 410 may be arranged in a pattern over the substrate 455. The pattern may be an asymmetric pattern that does not include an axis of symmetry. For example, any diameter D formed through the origin 456 of the substrate 455 at any angle may not be an axis of symmetry for the pattern of dielectric resonators 410. In some embodiments both the distance from the origin 456 of the substrate 455 to a center-point of each dielectric resonator 410 and an angle θ with respect to a radius R of the substrate 455 are different for each of the plurality of dielectric resonators 410. Though, in other embodiments, two or more dielectric resonators 410 may have either the same distance from the origin 456 to a center-point of the dielectric resonator 410 or the same angle θ relative to a radius R of the substrate 455. In the illustrated embodiment, the plurality of dielectric resonators 410 comprises a set of nine dielectric resonators 410. Though, embodiments may include any number of dielectric resonators 410.

Similar to the embodiment described with respect to FIG. 3A, rotating the substrate 455 may result in uneven exposure along the radius of the substrate 455 due to points near the origin 456 moving slower than points near the edge of the substrate 455 during rotation. Accordingly, embodiments may account for the lower effective plasma flux towards the edge of the substrate 455 by providing more dielectric resonators 410 proximate to an edge of the substrate 455. For example, in FIG. 4A, a first set of dielectric resonators 410_{A} may be proximate to the origin 456, and a second set of dielectric resonators 410_{B} may be proximate to the edge of the substrate 455. More specifically, the first set of dielectric resonators 410_{A} may be distinguished from the second set of dielectric resonators 410_{B} by a position of a center point of each dielectric resonator 410 relative to a boundary 457. For example, the boundary 457 may be one-half of the radius of the substrate 455 (e.g., R/2). As shown in FIG. 4A, the first set of dielectric resonators 410_{A} comprises two dielectric resonators 410_{A}, and the second set of dielectric resonators 410_{B} comprises seven dielectric resonators 410_{B}. Though, any suitable distribution of dielectric resonators between the two sets may be used in some embodiments.

While positioning of the dielectric resonators 410 may be used to balance the effective plasma flux along each radial position of the substrate 455, other embodiments may also include controlling power settings for the dielectric resonators 410. For example, the dielectric resonators 410 closer to an edge of the substrate 455 may be held at a higher power level than the dielectric resonators 410 closer to the origin 456.

Referring now to FIG. 4B, a graph of the plasma flux relative to a radial position from the origin (i.e., 0 mm) to an edge of the substrate (i.e., 150 mm) is shown, in accordance with an embodiment. The graph shows the relative contribution 431A-431E to the plasma flux from several of the individual dielectric resonators 410. When those contributions 431 are summed together, a total plasma flux 435 is provided. Compared to the total plasma flux 335 shown in FIG. 3B, the degree of uniformity is improved by providing more dielectric resonators. For example, the degree of uniformity may be approximately 95% or higher, approximately 97% or higher, or approximately 99% or higher.

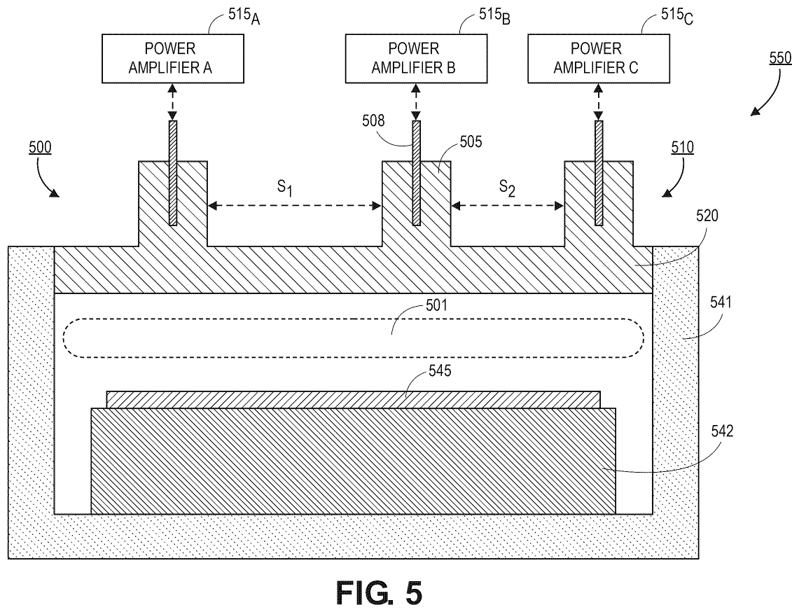

Referring now to FIG. 5, a cross-sectional illustration of a processing tool 550 for processing substrates 545 with a plasma process is shown, in accordance with an embodiment. In an embodiment, the processing tool 550 may be a microwave plasma chamber suitable for etching, deposition, plasma treatments, and/or the like. The processing tool 550 may comprise a chamber 541, such as a chamber 541 suitable for supporting a vacuum or the like. Exhaust lines, pumps, slit valves, gas inputs, and/or the like are omitted from the chamber 541 for simplicity. In an embodiment, a pedestal 542, heater, chuck, stage, or the like may be provided within the chamber 541 for supporting a substrate 545. In an embodiment, the pedestal 542 may be configured to rotate. The substrate 545 may be a semiconductor wafer of any form factor (e.g., 300 mm, etc.) or any other type of substrate suitable for processing with a plasma process.

In an embodiment, a microwave plasma source 500 may be provided as a lid or a part of a lid that seals the chamber 541. In an embodiment, the microwave plasma source 500 may comprise a dielectric plate 520 with a plurality of dielectric resonators 510 arranged in an asymmetrical pattern across the dielectric plate 520. While three dielectric resonators 510 are shown in FIG. 5, it is to be appreciated that the microwave plasma source 500 may comprise any number of dielectric resonators 510. In an embodiment, the spacing between the dielectric resonators 510 may be non-uniform (e.g., spacing S₁ is different than spacing S₂). In an embodiment, the dielectric resonators 510 may be substantially similar to any of the dielectric resonators described in greater detail herein. For example, the dielectric resonators 510 may comprise a dielectric puck 505 with an electrically conductive pin 508 inserted into the dielectric puck 505. Each of the dielectric resonators 510 may be electrically coupled to different microwave power amplifiers 515_{A}-515_{C} to allow for independent control of each dielectric resonator 510.

Similar to embodiments described herein, the rotation of the substrate 545 combined with the asymmetric pattern of the dielectric resonators 510 may allow for the generation of a plasma 501 within the chamber 541 that provides a high degree of plasma flux uniformity across the diameter of the substrate 545. For example, the degree of uniformity of the plasma flux across the diameter of the substrate 545 may be approximately 90% or higher, approximately 95% or higher, approximately 97% or higher, or approximately 99% or higher.

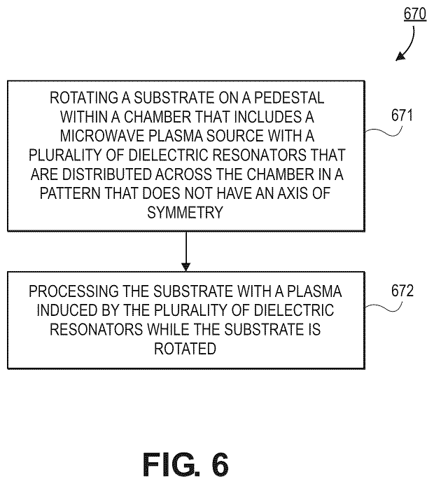

Referring now to FIG. 6, a flow diagram depicting a process 670 for processing a substrate with a microwave plasma process with a plasma that includes a plasma flux with a high degree of uniformity across a diameter of the substrate is shown, in accordance with an embodiment. In an embodiment, the process 670 may begin with operation 671, which comprises rotating a substrate on a pedestal within a chamber that comprises a microwave plasma source with a plurality of dielectric resonators. In an embodiment, the plurality of dielectric resonators are distributed across the chamber in a pattern that does not have an axis of symmetry. That is, the pattern may be considered asymmetric in some embodiments. In an embodiment, the plurality of dielectric resonators may include three or more dielectric resonators, seven or more dielectric resonators, or nine or more dielectric resonators. In an embodiment, the chamber and the microwave plasma source may be similar to any of the chambers and/or microwave plasma sources described in greater detail herein.

In an embodiment, the process 670 may continue with operation 672, which comprises processing the substrate with a plasma induced by the plurality of dielectric resonators while the substrate rotates. In some embodiments, the rotation of the substrate is controlled so that an integer number of rotations occur during the processing of the substrate. Providing an integer number of rotations of the substrate provides improved uniformity given the asymmetric pattern of the dielectric resonators. Stated differently, optimal plasma flux uniformity across the entire substrate surface may be obtained when one or more full rotations are used during the duration of the processing. In an embodiment, the processing of the substrate may include an etching process, a deposition process, a plasma treatment process, or the like. In an embodiment, a plasma flux towards the substrate may have a degree of uniformity that is approximately 90% or higher, approximately 95% or higher, approximately 97% or higher, or approximately 99% or higher. In an embodiment, the degree of uniformity may also be improved through the independent control of the microwave power delivered to each of the plurality of dielectric resonators.

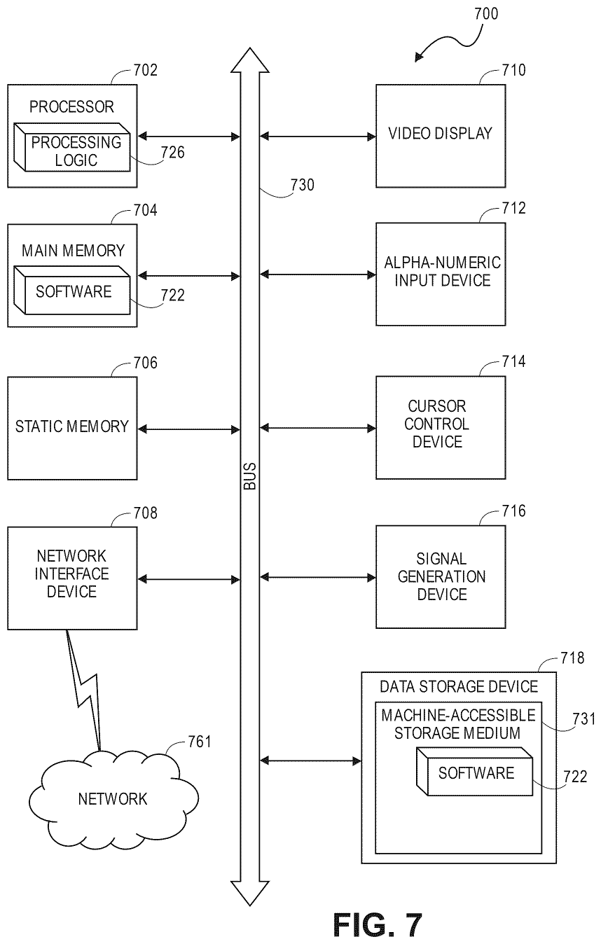

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using RF coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a dielectric plate; and
a plurality of dielectric resonators coupled to the dielectric plate, wherein the plurality of dielectric resonators are distributed across the dielectric plate in a pattern that is asymmetric.

2. The apparatus of claim 1, wherein each of the plurality of dielectric resonators comprise a pin inserted into a dielectric puck.

3. The apparatus of claim 2, wherein each of the plurality of dielectric resonators are electrically coupled to a different one of a plurality of microwave amplifiers, and wherein each of the plurality of microwave amplifiers are independently controllable.

4. The apparatus of claim 1, wherein the plurality of dielectric resonators comprises a first set of dielectric resonators and a second set of dielectric resonators, wherein the first set of dielectric resonators each have a center-point that is spaced from an origin of the dielectric plate by less than half of a radius of the dielectric plate and the second set of dielectric resonators have a center-point that is spaced from the origin of the dielectric plate by more than half of the radius of the dielectric plate.

5. The apparatus of claim 4, wherein the first set of dielectric resonators has a first number of dielectric resonators and the second set of dielectric resonators has a second number of dielectric resonators that is greater than the first number of dielectric resonators.

6. The apparatus of claim 1, wherein the plurality of dielectric resonators comprises four or more dielectric resonators.

7. The apparatus of claim 1, wherein the plurality of dielectric resonators are configured to ignite a plasma below the dielectric plate with a degree of uniformity that is at least 90% from a center to an edge of a substrate that is to be positioned below the dielectric plate.

8. The apparatus of claim 7, wherein the degree of uniformity is at least 97%.

9. The apparatus of claim 1, wherein the plurality of dielectric resonators are each positioned at different angles relative to a radius of the dielectric plate.

10. The apparatus of claim 9, wherein the plurality of dielectric resonators are each positioned at a different distance from an origin of the dielectric plate.

11. The apparatus of claim 1, wherein none of the plurality of dielectric resonators have a center point that is coincident with an origin of the dielectric plate.

12. An apparatus, comprising:
a chamber;
a microwave plasma source coupled to the chamber, wherein the microwave plasma source comprises a plurality of dielectric resonators that are distributed over a dielectric plate, and wherein a pattern of the plurality of dielectric resonators does not include an axis of symmetry; and
a pedestal within the chamber, wherein the pedestal is configured to be rotated.

13. The apparatus of claim 12, wherein the plurality of dielectric resonators are independently controllable.

14. The apparatus of claim 12, wherein the plurality of dielectric resonators comprises five or more dielectric resonators.

15. The apparatus of claim 12, wherein the plurality of dielectric resonators are configured to ignite a plasma within the chamber with a degree of uniformity that is at least 95% from a center to an edge of a substrate that is to be positioned on the pedestal.

16. The apparatus of claim 12, wherein the plurality of dielectric resonators are each positioned at different angles relative to a radius of the dielectric plate.

17. The apparatus of claim 16, wherein the plurality of dielectric resonators are each positioned at a different distance from an origin of the dielectric plate.

18. A method, comprising:
rotating a substrate on a pedestal within a chamber that comprises a microwave plasma source with a plurality of dielectric resonators that are distributed across the chamber in a pattern that does not have an axis of symmetry; and
processing the substrate with a plasma induced by the plurality of dielectric resonators while the substrate is rotated.

19. The method of claim 18, wherein the plasma has a degree of uniformity is at least 95% from a center to an edge of a substrate.

20. The method of claim 18, wherein the substrate undergoes an integer number of full rotations during the processing.
